(19) United States
(12) Patent Application Publication
(10) Pub. No.: US 2026/0321322 A1
(43) Pub. Date: Oct. 15, 2026

(54) METHOD FOR PREDICTING BEHAVIOR OF MEMORY DEVICE, ELECTRONIC APPARATUS PERFORMING THE SAME AND NON-TRANSITORY COMPUTER READABLE MEDIUM

(71) Applicant: SAMSUNG ELECTRONICS CO., LTD., Suwon-si (KR)

(72) Inventors: Bo Kyeom KIM, Suwon-si (KR); Ui Hui KWON, Suwon-si (KR); Woon Ih CHOI, Suwon-si (KR)

(73) Assignee: SAMSUNG ELECTRONICS CO., LTD., Suwon-si (KR)

(21) Appl. No.: 19/643,394

(22) Filed: Apr. 9, 2026

(30) Foreign Application Priority Data
Apr. 9, 2025 (KR) 10-2025-0046376
Jul. 15, 2025 (KR) 10-2025-0095281

(51) Int. Cl. G11C 16/34

(52) U.S. Cl. CPC G11C 16/3431

(57) ABSTRACT

A method for predicting an operation of a memory device performed by a processor includes determining injection energy of an electron injected into the memory device, in a simulation, determining scattering degree of an electron in a charge trap layer based on the injection energy, obtaining kinetic energy of the electron in the charge trap layer based on the scattering degree, and adjusting an electron capture cross section based on the kinetic energy of the electron.

### CROSS REFERENCE TO RELATED APPLICATION

This application is based on and claims priority from Korean Patent Application No. 10-2025-0046376 filed on Apr. 9, 2025, and No. 10-2025-0095281 filed on Jul. 15, 2025, in the Korean Intellectual Property Office, the disclosures of which are herein incorporated by reference in their entireties.

### BACKGROUND

### 1. Field

The disclosure relates to relates to a method for predicting an operation of a memory device, an electronic apparatus for performing the same, and a non-transitory computer-readable medium therefor.

### 2. Description of Related Art

Among memory devices, charge trap flash (CTF) memory cells have a structure which stores charge in a charge trap layer rather than a floating gate. For designing a memory apparatus including such a memory device, it is required to accurately predict operating characteristics of the memory device (e.g., change in a threshold voltage depending on a program voltage). Accurate prediction of the operating characteristics of the memory device may be achieved only when physical mechanisms on behavior of electrons are considered in a simulation process for predicting the operating characteristics of the memory device.

### SUMMARY

Aspects of the disclosure provide a method for predicting an operation of the memory device.

Aspects of the disclosure also provide an electronic apparatus for executing the method for predicting operation of the memory device.

Aspects of the disclosure also provide a non-transitory computer-readable medium that stores a computer program for executing the method for predicting operation of the memory device.

According to an aspect of some embodiments of disclosure, there is provided a method for predicting an operation of a memory device performed by a processor, the method comprising: determining an injection energy of an electron injected into the memory device, in a simulation; determining a scattering degree of an electron in a charge trap layer based on the injection energy; obtaining a kinetic energy of the electron in the charge trap layer based on the scattering degree; and adjusting an electron capture cross section based on the kinetic energy of the electron.

According to an aspect of some embodiments of disclosure, there is provided an electronic apparatus comprising a processor and a memory storing instructions, wherein the instructions, when executed by the processor, cause the processor to perform: determining an injection energy of an electron injected into a memory device, in a simulation; determining a scattering degree of an electron in a charge trap layer based on the injection energy; obtaining a kinetic energy of the electron in the charge trap layer based on the scattering degree; and adjusting an electron capture cross section based on the kinetic energy of the electron.

According to some embodiments of disclosure, there is provided a non-transitory computer-readable medium that stores a computer program, which, when executed by a processor, causes the processor to perform: determining an injection energy of an electron injected into a memory device, in a simulation; determining a scattering degree of an electron in a charge trap layer based on the injection energy; obtaining a kinetic energy of the electron in the charge trap layer based on the scattering degree; and adjusting an electron capture cross section based on the kinetic energy of the electron.

However, aspects of the disclosure are not restricted to the one set forth herein. The above and other aspects of the disclosure will become more apparent to one of ordinary skill in the art to which the disclosure pertains by referencing the detailed description of the disclosure given below.

Specific details of other embodiments are included in the detailed description and drawings.

### BRIEF DESCRIPTION OF THE DRAWINGS

The above and other aspects, features, and advantages of certain example embodiments of the disclosure will be more apparent from the following description taken in conjunction with the accompanying drawings, in which:

FIG. 1 is a flowchart for explaining a method for predicting an operation of a memory device according to some embodiments;

FIG. 2 is a diagram for explaining an example of a structure of a memory device to be simulated;

FIG. 3 is a flowchart for explaining a method for predicting an operation of a memory device according to some embodiments;

FIG. 4 is a diagram for explaining injection energy of electrons;

FIG. 5 is a diagram for explaining an energy of electrons in a charge trap layer;

FIG. 6 is a diagram for explaining capturing of electrons in a charge trap layer;

FIG. 7 is a graph showing a difference between simulation values and experimental values obtained through simulation according to a comparative example;

FIG. 8 is a graph that shows a difference between simulation values and experimental values obtained through simulations according to some embodiments; and

FIG. 9 is a block diagram for explaining an electronic apparatus for performing a method according to some embodiments.

### DETAILED DESCRIPTION

Example embodiments according to the technical concepts of the disclosure will be described below referring to the accompanying drawings.

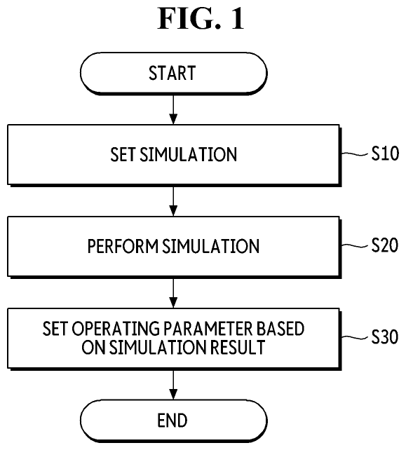

FIG. 1 is a flowchart for explaining a method for predicting an operation of a memory device according to some embodiments.

Referring to FIG. 1, a simulation may be set in operation S10. The simulation may be performed to predict the operation of the memory device. The simulation may be performed, using a simulation tool. The simulation tool may be, for example, but is not limited to, a technology computer-aided design (TCAD) simulator. A simulation setting operation may include, for example, setting of a predetermined program voltage. The program voltage may be applied to a gate electrode of the memory device to form an electric field between a channel and the gate electrode. The simulation setting operation may include, for example, setting of characteristic parameters of the memory device. The memory device may be, for example, a charge trap flash (CTF) memory cell used in a NAND flash memory. The CTF memory cell may include, for example, a channel layer, a tunnel oxide film layer, a charge trap layer, a blocking oxide film layer, and a gate electrode. Parameters such as physical properties and thicknesses of materials included in the memory device may be set in the simulation setting operation.

According to some embodiments, the simulation may be performed in operation S20. In a simulation performing operation, electrons may be injected toward the charge trap layer in the memory device. Various physical mechanisms may be applied to observe a behavior of the injected electrons in the simulation performing operation. The behavior of electrons actually injected toward the charge trap layer in the memory device may be predicted through the observed behavior of the electrons, thereby predicting the operation of the memory device.

In the simulation performing operation, for example, injection energy of injected electrons may be determined. After that, a scattering degree of electrons in the charge trap layer may be determined depending on the determined injection energy. Next, kinetic energy of electrons in the charge trap layer may be calculated based on the determined scattering degree. Next, a capture cross section of an electron (or electron capture cross section) in the charge trap layer may be adjusted depending on the calculated kinetic energy of the electron. After that, simulation values may be obtained based on the adjusted capture cross section. For example, a Poisson equation, a drift-diffusion equation, and a trap equation substituted with the adjusted capture cross section may be simultaneously solved, and a numerical solution that satisfies all of the equations may be calculated to obtain a potential, a charge density, a threshold voltage, and the like of the memory device.

According to some embodiments, memory operating parameters may be set based on the simulation results in operation S30. The operation S30 may be a subsequent operation after performing the simulation. The simulation results may be used to set various operating parameters of a memory in a process of designing, manufacturing, testing and/or using a memory semiconductor. For example, a threshold voltage value corresponding to a set program voltage value may be obtained by performing the simulation. An optimal program voltage for the CTF memory cell may be determined by repeatedly performing the simulation. In addition, optimal incremental step pulse programming (ISPP) operating parameters (such as voltage magnitude, pulse timing, etc.) for the CTF memory cell may be determined.

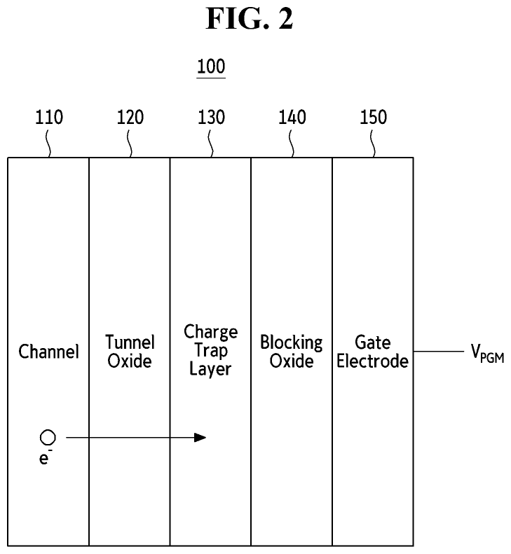

FIG. 2 is a diagram for explaining an example of a structure of a memory device to be simulated.

Referring to FIG. 2, a memory device 100 may be one of a plurality of memory cells included in a memory cell array that constitutes a memory apparatus. The memory device 100 may be, for example, but is not limited to, a CTF memory cell. For convenience of explanation, the following description will be given assuming that the memory device 100 is a CTF memory cell. The memory device 100 may have a SONOS structure. That is, the memory device 100 may include a channel 110, a tunnel oxide film 120, a charge trap layer 130, a blocking oxide film 140, and a gate electrode 150. The channel 110 may function as a source of electrons injected into the memory device 100. The channel 110 may include, but is not limited to, silicon (Si), germanium (Ge), silicon-germanium (SiGe), gallium arsenide (GaAs), and the like.

The tunnel oxide film 120 may function as a path for electrons at the time of program and/or erase operations of the memory cell. At the time of the program operation of the memory device 100, electrons may pass through the tunnel oxide film 120 and move toward the charge trap layer 130 by a Fowler-Nordheim (FN) tunneling phenomenon. The tunnel oxide film 120 may include, but is not limited to, silicon dioxide (SiO₂), silicon oxynitride (SiON), hafnium oxide (HfO₂), or the like.

The charge trap layer 130 may be a layer in which injected electrons and/or holes are captured. The threshold voltage of the memory cell may be determined by the captured electrons and/or holes. The charge trap layer 130 may include, but is not limited to, silicon nitride (SiN), hafnium oxide (HfO₂), or the like.

The blocking oxide film 140 may block the movement of electrons or holes from the charge trap layer 130 toward the gate electrode 150 or from the gate electrode 150 toward the charge trap layer 130. The blocking oxide film 140 may include, but is not limited to, silicon dioxide (SiO₂), hafnium oxide (HfO₂), or the like.

The memory apparatus may perform read, program, and/or erase operations on the memory device 100 by applying a voltage to the gate electrode 150. The memory apparatus may apply a program voltage V_{PGM} to the gate electrode 150 to form an electric field in the memory device 100. Electrons located at the channel 110 may be injected into the charge trap layer 130 by the electric field formed by the program voltage V_{PGM}.

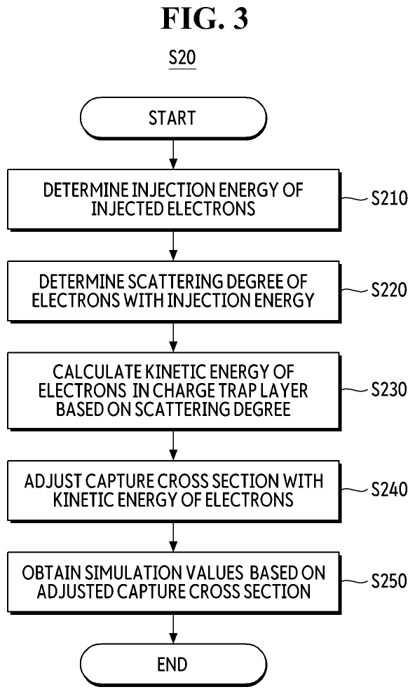

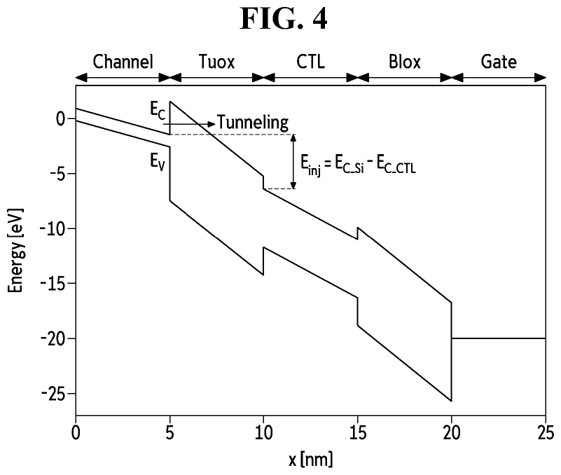

FIG. 3 is a flowchart for explaining a method for predicting the operation of the memory device according to some embodiments. FIG. 4 is a diagram for explaining injection energy of electrons.

Referring to FIG. 3, a method (S20) may correspond to an operation of performing the simulation described in FIG. 1. The method (S20) described below may be performed on the simulation.

According to some embodiments, the method (S20) may include an operation (S210) of determining injection energy of injected electrons on the simulation. Due to electric fields formed in the memory device, electrons located at the channel may move toward the charge trap layer. In general, to overcome an energy barrier due to an insulating layer, electrons need to have enough energy that may overcome the energy barrier. If a strong electric field is formed on a thin insulating layer, electrons may pass through the insulating layer through a Fowler Nordheim (FN) tunneling phenomenon.

The injection energy of electrons will be explained referring to FIG. 4 together. In an energy band diagram shown in FIG. 4, an x-axis represents a vertical distance from a reference point of the channel to the gate, and a y-axis represents an energy magnitude. Electrons that have passed through the tunnel oxide film may enter the charge trap layer in a high-energy state. An initial energy of electrons entering the charge trap layer may be defined as an injection energy (Eᵢₙⱼ). The injection energy may refer to a kinetic energy that electrons passing through the tunnel oxide possess when entering the charge trap layer. The injection energy may be determined by modeling as following equations:

Eᵢₙⱼ=E_{C_Si}−E_{C_CTL}

Here, E_{C_Si} is a conduction band minimum energy at an interface between the channel and the tunnel oxide, and E_{C_CTL} is a conduction band minimum energy at an interface between the tunnel oxide film and the charge trap layer.

According to some embodiments, the method (S20) may include an operation (S220) of calculating the scattering degree inside the charge trap layer based on the injection energy. Electrons that pass through the tunnel oxide film and enter the charge trap layer lose energy or change in direction by a scattering phenomenon. For example, incident electrons may lose energy and change in direction due to phonon scattering caused by interactions with phonons. A phonon scattering degree due to phonon scattering increases with a magnitude of energy of the particle. The reason is that higher-energy electrons collide with more phonons and release more energy. Based on experimental data and simulation results, the scattering degree due to injection energy may be determined by modeling as follows:

λ(Eᵢₙⱼ)=exp(C₁-C₂·Eᵢₙⱼ)
λ(Eᵢₙⱼ) is an average distance (energy relaxation length) required to reduce the energy of electrons by 1 eV, Eᵢₙⱼ is an injection energy, and C₁ and C₂ are constants that are set when modeling. The scattering degree is a reciprocal of λ(Eᵢₙⱼ). Therefore, the scattering degree may increase exponentially according to the magnitude of the injection energy.

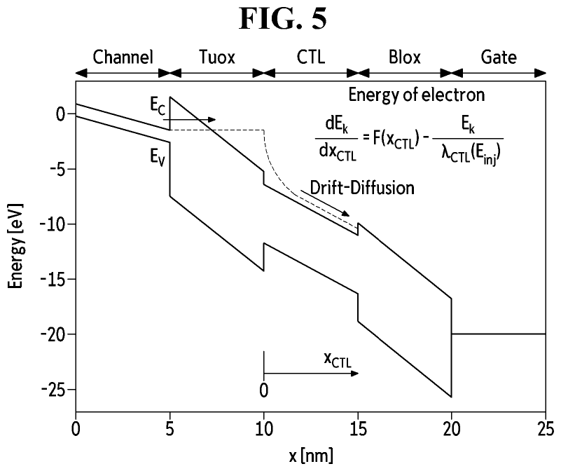

FIG. 5 is a diagram for explaining the energy of electrons in the charge trap layer.

According to some embodiments, the method (S20) may include an operation (S230) of calculating the energy of electrons in the charge trap layer based on the scattering degree. The energy of electrons in the charge trap layer will be explained referring to FIG. 5. In an energy band diagram shown in FIG. 5, an x-axis represents a vertical distance from the reference point of the channel to the gate, and a y-axis represents an energy magnitude. Electrons that enter the charge trap layer may drift and diffuse inside the charge trap layer. The electrons may have increased energy due to an electric field, and lose energy through scattering, or the like. Taking this into account, the kinetic energy of electrons in the charge trap layer may be modeled in the form of a first-order differential equation as follows:

$$\frac{{dE}_{k}}{{dx}_{CTL}} = F ( {x}_{CTL} ) - \frac{{E}_{k}}{λ ( {E}_{inj} )}$$

x_{CTL} is a vertical distance from the interface between the tunnel oxide film and the charge trap layer to the gate, Eₖ is a kinetic energy of an electron,

$$\frac{{dE}_{k}}{{dx}_{CTL}}$$

is an energy change rate of the electron, F(x_{CTL}) is an electric force acting on the electron, and λ(Eᵢₙⱼ) is an energy relaxation length (a reciprocal of the scattering degree) obtained in operation S220. At this time, Eₖ(0)-Eᵢₙⱼ. A kinetic energy of an electron that depends on a position of the electron in the charge trap layer may be calculated by integrating the above first-order differential equation according to a position of the electron.

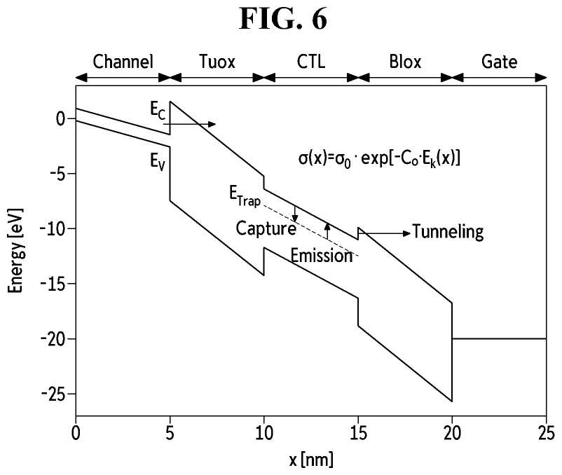

FIG. 6 is a diagram for explaining capturing of electrons in the charge trap layer.

According to some embodiments, the method (S20) may include an operation of adjusting the capture cross section of electrons based on the kinetic energy. Capturing of electrons in the charge trap layer will now be described referring to FIG. 6 together. In an energy band diagram shown in FIG. 6, an x-axis represents a vertical distance from the reference point of the channel to the gate, and a y-axis represents an energy magnitude.

Electrons that drift and diffuse inside the charge trap layer may be captured by a multi-phonon transition effect. For example, the electrons may emit multiple phonons and transition (be captured) to the trap energy (E_{Trap}) band, and the captured electrons may absorb multiple phonons and transition back them to the conduction band (E_{C}). The capturing rate of electrons may be proportional to the magnitude of the capture cross section. The magnitude of the capture cross section may be determined by the energy of electrons. The magnitude of the capture cross section may become smaller for higher energy of electrons and become larger for lower energy of electrons. Based on experimental data and simulation results, the capture cross section σ(x) of electrons depending on the energy of electrons may be modeled as follows:

σ(x)=σ₀·exp[−C₀·Eₖ(x)]

σ₀ is a magnitude of a fixed capture cross section, C₀ is a constant that is set when modeling, and Eₖ(x) is the energy of electrons in the charge trap layer.

According to some embodiments, the method (S20) may include an operation (S250) of obtaining simulation values based on the adjusted capture cross section. When the characteristics of the charge trap layer, including the adjusted capture cross section, are obtained, a numerical solution that simultaneously solves the Poisson equation, drift-diffusion equation, and trap equation, and satisfies all these equations may be calculated.

The Poisson equation calculates the electric potential through the net charge density ρ, and is as follows:

∇·(ϵᵣ·ϵ₀∇V)=−ρ=−q(p−n+N_{D}−N_{A})+ρₜᵣₐₚ

V is an electric potential, p and n are hole and electron densities, respectively, N_{D} and N_{A} are doping concentrations of a donor and an acceptor, ρₜᵣₐₚ is a density of the captured charge, and ϵᵣ and ϵ₀ are relative permittivity and vacuum permittivity, respectively.

The drift-diffusion equation is an equation that calculates the electron density through the electric potential and density, and as follows:

$$\frac{\partial n}{\partial t} = - \frac{1}{q} ∇ \cdot {J}_{n} - {R}_{n} = - \frac{1}{q} ∇ \cdot ( {μ}_{n} n ∇ V - {D}_{n} ∇ n ) - {R}_{n}$$

Jₙ is a current density of electron, μₙ and Dₙ are mobility and diffusion coefficient of electrons, respectively, and Rₙ is a net recombination rate of electrons.

The trap equation is an equation that calculates an occupancy function (f) that represents how many electrons are filled in the trap in consideration of a capturing rate of electrons and an emission rate of electrons, and as follows:

$$\frac{\partial f}{\partial t} = {c}_{n} ( 1 - f ) - {e}_{n} f$$

Here, cₙ and eₙ are the capturing rate of electrons and the emission rate of electrons, respectively, and may be obtained through the following formula:

$${c}_{n} = {σ}_{n} {v}_{th , n} n , {e}_{n} = {σ}_{n} {v}_{th , n} {N}_{C} exp ( - \frac{{E}_{T}}{{k}_{B} T} )$$

σₙ is the capture cross section electrons, v_{th,n} is a thermal velocity of electrons, N_{C} is an effective density of states of the conduction band, and E_{T} is a trap depth in comparison to the conduction band.

When obtaining an occupation function (f), it may calculate how many electrons are captured in the conduction band by traps (R_{n,trap}), which may be added to the net recombination rate term in the drift-diffusion equation.

R_{n,trap}=N_{T}·(cₙ·(1−ƒ)−eₙ·ƒ)

N_{T} is a trap density. As above, when obtaining the numerical solution by simultaneously solving the Poisson equation, drift-diffusion equation, and trap equation, it is possible to obtain simulation values such as the captured charge distribution, potential distribution, electron density, and threshold voltage value. However, the method for obtaining simulation values (e.g., captured charge distribution, potential distribution, electron density, and threshold voltage value) based on the adjusted capture cross section is not limited to the above method, and the simulation value may be obtained through various methods.

As an example of the method for obtaining the threshold voltage value, the distribution depending on the position of captured charge (ρₜᵣₐₚ(x)) may be calculated based on the adjusted charge capture cross section according to the following formula:

ρₜᵣₐₚ(x)=ƒ(x)·Nₜᵣₐₚ(x)

Nₜᵣₐₚ(x) is a trap density depending on the position, and f(x) is the occupancy function mentioned above.

A total charge amount (Q_{tot,trap}) stored in the trap layer may be obtained by the following formula:

Q_{tot,trap}=q∫ₓ_{_{CTL}}Nₜᵣₐₚ(x)·f(x)dx

The change in the threshold voltage due to the amount of trap charge may be calculated by the following formula:

$${ΔV}_{T} = \frac{{Q}_{tot , trap}}{{C}_{tot}}$$

Here, Cₜₒₜ is a total capacitance between the channel and gate, which may be calculated in the following formula:

$${C}_{tot} = \frac{1}{\frac{1}{{C}_{Tuox}} + \frac{1}{{C}_{CTL}} + \frac{1}{{C}_{Blox}}} = \frac{1}{\frac{{T}_{Tuox}}{{ϵ}_{0} {ϵ}_{Tuox}} + \frac{{T}_{CTL}}{{ϵ}_{0} {ϵ}_{CTL}} + \frac{{T}_{Blox}}{{ϵ}_{0} {ϵ}_{Blox}}}$$

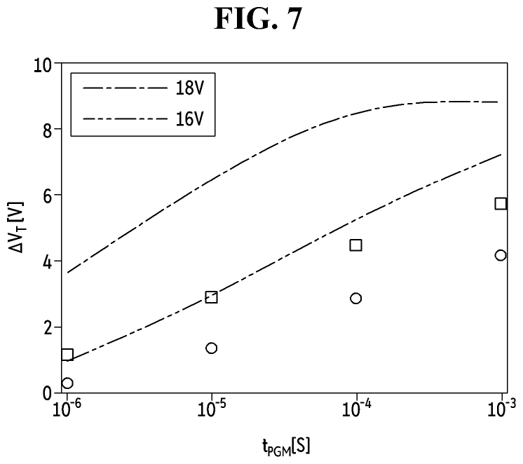

FIG. 7 is a graph showing a difference between simulation values and experimental values obtained through simulation according to a comparative example.

Referring to FIG. 7, an x-axis of the graph represents a program time t_{PGM}, and a y-axis represents a change in a threshold voltage ΔV_{T}. A dashed-dotted line in the graph represents simulated results of the change in the threshold voltage ΔV_{T} with the program time t_{PGM} when the program voltage magnitude V_{PGM} is 18V, and a dashed-two-dotted line represents simulated results of the change in threshold voltage ΔV_{T} with the program time t_{PGM} when the program voltage magnitude V_{PGM} is 16V. Square markers in the graph represent experimental values of the change in the threshold voltage ΔV_{T} with the program time t_{PGM} when the program voltage magnitude V_{PGM} is 18V, and circular markers represent experimental values of the change in the threshold voltage ΔV_{T} with the program time t_{PGM} when the program voltage magnitude V_{PGM} is 16V.

The simulation of FIG. 7 shows the results of simulation values obtained based on a fixed capture cross section without considering changes in energy of electrons in the charge trap layer. Since this simulation does not consider energy of electrons, it is calculated that electrons are captured in the traps as soon as they enter the charge trap layer. Accordingly, it is calculated that, simply when the program voltage is high, the amount of tunneled electrons increases, and more electrons are captured. In other words, this simulation overestimates the change in the threshold voltage according to an increase in the program voltage because it fails to reflect a phenomenon in which high-energy electrons are not captured in the charge trap layer but flow.

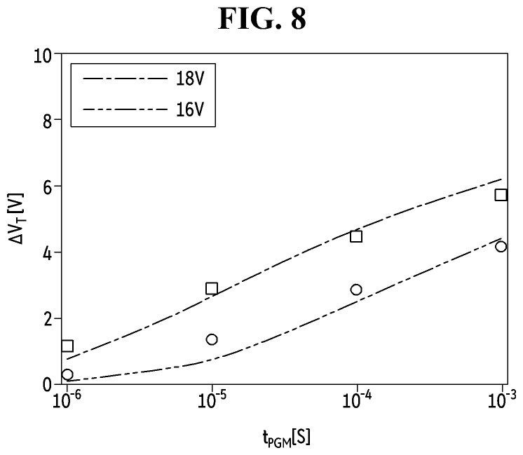

FIG. 8 is a graph that shows the difference between simulation values and experimental values obtained through simulations according to some embodiments.

Referring to FIG. 8, an x-axis of the graph represents the program time t_{PGM}, and a y-axis represents the change in the threshold voltage value ΔV_{T}. The dashed-dotted line on the graph represents the simulated results of the change in the threshold voltage value ΔV_{T} with the program time t_{PGM} when the program voltage V_{PGM} is 18 V, and the dashed-two-dot line represents the simulated results of the change in the threshold voltage value ΔV_{T} with the program time t_{PGM} when the program voltage V_{PGM} is 16 V. Square markers on the graph represent experimental values of the change in the threshold voltage value ΔV_{T} with the program time t_{PGM} when the program voltage V_{PGM} is 18 V, and circular markers represent experimental values of the change in the threshold voltage value ΔV_{T} with the program time t_{PGM} when the program voltage V_{PGM} is 16 V.

The simulation of FIG. 8 shows the results of simulation values obtained based on the capture cross section adjusted in consideration of a change in energy of electrons in the charge trap layer. In this simulation, the capture cross section is adjusted taking into account the energy of electrons. This prevents overestimation of the change in the threshold voltage value according to an increase in the program voltage, thereby significantly reducing an error between the simulated and experimental values. Therefore, the method for predicting the operation of a memory device according to some embodiments may provide more accurate modeling of the memory device.

If the change in the scattering degree depending on the magnitude of injection energy is not taken into account when calculating the energy of electrons, it is assumed that electrons will lose energy equally when the program voltage V_{PGM} is high (e.g., 18 V) and low (e.g., 16 V). As the program voltage V_{PGM} increases, electrons have higher energy in the charge trap layer. Accordingly, it is possible to calculate that the capturing probability of electrons further decreases as the program voltage V_{PGM} increases. As a result, it is predicted that the program efficiency will decrease as the program voltage V_{PGM} increases. In this simulation according to some embodiments, because the change in the scattering degree due to the injection energy of electrons is taken into account, it is possible to prevent a phenomenon in which the program efficiency is predicted to further decrease as the program voltage V_{PGM} increases. Therefore, the method for predicting the operation of the memory device according to some embodiments may provide more accurate modeling of the memory device.

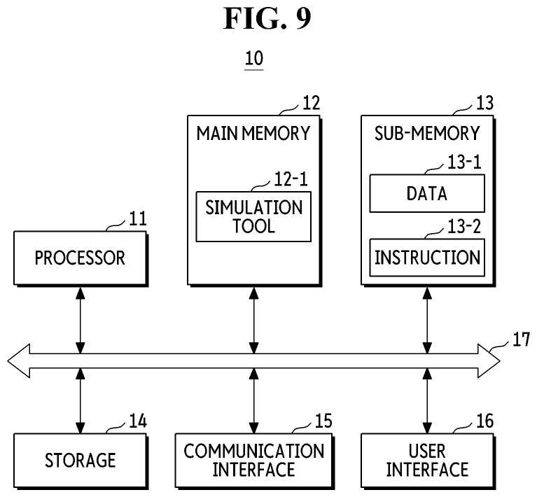

FIG. 9 is a block diagram for explaining an electronic apparatus for performing the method according to some embodiments. In detail, FIG. 9 is a block diagram of an electronic apparatus 10 that executes the method(s) for predicting operation of the memory device described referring to FIGS. 1 to 8. The following description will be made referring to FIGS. 1 to 8, the same reference numerals denote the same components, and repeated description will not be provided.

Referring to FIG. 9, the electronic apparatus 10 may include a processor 11, a main memory 12, a sub-memory 13, a storage 14, a communication interface 15, a user interface 16, and a bus 17. The electronic apparatus 10 may be part of a semiconductor simulation system. The semiconductor simulation system may include various design and verification simulation programs. The electronic apparatus 10 may be implemented as a general-purpose computer or a special-purpose computer for semiconductor simulation.

The processor 11 may control the electronic apparatus 10 and perform the method for predicting operation of the memory device. The processor 11 may execute software executed by the electronic apparatus 10. The software may include application program, an operating system, a device driver, and the like. The processor 11 may execute the operating system stored in the main memory 12. The processor 11 may execute various application programs that are driven based on the operating system. For example, the processor 11 may execute a tool for simulation by executing instructions 13-2 stored in the sub-memory 13. For example, the processor 11 may execute a simulation tool 12-1 stored in the main memory 12. Thus, the processor 11 may perform at least some of a series of methods (S10, S20, and S30).

For example, the processor 11 may set characteristic parameters of the memory device for simulation, using data 13-1 stored in the sub-memory 13. The processor 11 may perform various simulations on the memory device, using the simulation tool 12-1 stored in the main memory 12. The processor 11 may receive simulation results from the simulation tool 12-1 and provide them to outside. The simulation results may be used to set various operating parameters of the memory in a process of designing, manufacturing, testing, and/or using the memory semiconductor.

The main memory 12 may be an operating memory of the processor 11. The main memory 12 may store application program, operating system, device driver, and the like executed by the processor 11. For example, the main memory 12 may store the simulation tool 12-1. The simulation tool 12-1 may be an application program for performing the simulation according to a method for predicting operation of the memory device. The simulation tool 12-1 may perform the simulation for obtaining simulation values of the memory device. The simulation values may include, for example, the potential, charge density, and threshold voltage values formed in the memory device. The simulation tool 12-1 may be executed through the processor 11.

The main memory 12 may temporarily store the data 13-1 and/or the instructions 13-2 required by the processor 11 among the data 13-1 and the instructions 13-2 stored in the sub-memory 13. The main memory 12 may include at least one of a volatile memory and a non-volatile memory. For example, the main memory 12 may include at least one of a read-only memory (ROM), a programmable ROM (PROM), an electrically programmable ROM (EPROM), an electrically erasable and programmable ROM (EEPROM), a flash memory, a phase-change RAM (PRAM), a magnetic RAM (MRAM), a resistive RAM (RRAM), a ferroelectric RAM (FRAM), a dynamic RAM (DRAM), a static RAM (SRAM), a synchronous DRAM (SDRAM), a phase-change RAM (PRAM), a magnetic RAM (MRAM), a resistive RAM (RRAM), and a ferroelectric RAM (FeRAM).

The sub-memory 13 may be an auxiliary memory (secondary memory) of the electronic apparatus 10. The sub-memory 13 may store the data 13-1 and the instructions 13-2. For example, the sub-memory 13 may store characteristic parameters of the memory devices for setting the simulation before performing the simulation, and may store execution instructions of the tool for performing the simulation. Information for setting the simulation, such as characteristic parameters of the memory devices, may be transmitted to the sub-memory 13 through the communication interface 15 or the storage 14 in the form of the data 13-1. The tool for performing the simulation may be transmitted to the sub-memory 13 through the modem 15 or the detachable storage device 14 in the form of the instructions 13-2.

The sub-memory 13 may include a memory card (e.g., a multi-media card (MMC), an embedded multi-media card (eMMC), a secure digital (SD), a MicroSD, etc.), a hard disk drive (HDD), a solid state drive (SSD), an optical disk drive (ODD), or the like. The sub-memory 13 may include a NAND-type flash memory. However, the sub-memory 13 is not limited thereto, and may include a next-generation non-volatile memory such as a phase-change random access memory (PRAM), a magnetic RAM (MRAM), a resistive RAM (ReRAM) and a ferroelectric RAM (FRAM), or a NOR flash memory, without being limited thereto.

The storage 14 may include a detachable portable storage. For example, the data 13-1 and the instructions 13-2 stored in the sub-memory 13 may be transferred from the storage 14 to the sub-memory 13. The storage 14 may be based on one of various standards, such as a Universal Serial Bus (USB) or a Serial Advanced Technology Attachment (SATA).

The communication interface 15 may communicate with external apparatuses in wired or wireless manner. For example, the data 13-1 and the instructions 13-2 may be stored in the sub-memory 13 from an external apparatus through the communication interface 15. The data 13-1 and the instructions 13-2 stored in the sub-memory 13 may be transmitted to an external apparatus through the communication interface 15. The communication interface 15 may be based on Ethernet.

The user interface 16 may receive simulation execution instructions of tool for simulation and various instructions for the simulation functions of tool from the user. For example, the user may directly input information required for the simulation, such as characteristic parameters of memory devices and program voltages V_{PGM}, before performing the simulation. The user interface 16 may include various user input interface apparatuses, such as a touch sensor, a keyboard, a mouse, and a pointing apparatus, but is not limited thereto.

The user interface 16 may transmit a process and results of the simulation according to some embodiments to the user. The user interface 16 may include various user output interface apparatuses, such as a monitor and a printer. The user interface 16 may display the results of the simulation through the user output interface apparatus.

The bus 17 may provide a network inside the electronic apparatus 10. The processor 11, the main memory 12, the sub-memory 13, the storage 14, the communication interface 15, and the user interface 16 may be electrically connected and may exchange data with each other through the bus 17.

According to some embodiments, when the processor 11 of the electronic apparatus 10 executes the instruction 13-2, the instruction 13-2 may cause the processor 11 to perform an operation of determining the injection energy of injected electrons on the simulation, an operation of determining the scattering degree in the charge trap layer based on the injection energy, an operation of calculating kinetic energy in the charge trap layer based on the scattering degree, and an operation of adjusting the capture cross section of electrons based on the kinetic energy.

According to some embodiments, a non-transitory computer-readable medium having a computer program stored thereon is provided, and when the computer program is executed, the simulation that performs the method(s) for predicting operation of the memory device described above in FIGS. 1 to 8 may be implemented. For example, the processor may execute the computer program stored on the non-transitory computer-readable medium, and perform an operation of determining the injection energy of injected electrons on the simulation, an operation of determining the scattering degree in the charge trap layer based on the injection energy, an operation of calculating kinetic energy in the charge trap layer based on the scattering degree, and an operation of adjusting the capture cross section of electrons based on the kinetic energy

The computer-readable recording medium may be, for example, but is not limited to, an electrical, magnetic, optical, electromagnetic, infrared, semiconductor system, semiconductor apparatus, or any combination thereof. More specific examples of the computer-readable recording medium may include an electrical connection using one or more electric wires, a portable computer disk, a hard disk, a random access memory (RAM), a read-only memory (ROM), an erasable programmable read-only memory (EPROM or flash), an optical fiber, a portable compact disk read-only memory (CD-ROM), an optical storage device, a magnetic storage device, or suitable combinations thereof. In some embodiments, the computer-readable recording medium may be any type of medium that includes or stores a computer program usable by or in conjunction with an instruction execution system, device, or apparatus. The computer program included in the computer-readable recording medium may be transmitted, using any suitable medium, including, but not limited to, wire, optical fiber cable, radio frequency (RF), or the like, or any suitable combination thereof. The computer-readable recording medium may be included in any apparatus, or may exist independently without being integrated into the apparatus. Furthermore, according to some embodiments, a computer program product is also provided, and the instructions of the computer program product may be executed by a processor of a computer apparatus to perform the above-described method for predicting operation of the memory device.

Although some example embodiments of the disclosure have been described above with reference to the accompanying diagrams, the disclosure may not be limited to some embodiments and may be implemented in various different forms. Those of ordinary skill in the technical field to which the disclosure belongs are to appreciate that the disclosure may be implemented in other specific forms without changing the technical idea or essential features of the disclosure. Therefore, it should be understood that some embodiments as described above are not restrictive but illustrative in all respects.

What is claimed is:

1. A method for predicting an operation of a memory device performed by a processor, the method comprising:
determining an injection energy of an electron injected into the memory device, in a simulation;
determining a scattering degree of an electron in a charge trap layer based on the injection energy;
obtaining a kinetic energy of the electron in the charge trap layer based on the scattering degree; and
adjusting an electron capture cross section based on the kinetic energy of the electron.

2. The method of claim 1, wherein the scattering degree increases exponentially according to a magnitude of the injection energy.

3. The method of claim 2, wherein the determining the scattering degree comprises:
modeling an energy relaxation length by using a function having a natural constant as its base and the injection energy as its exponent, to determine the scattering degree; and
wherein the energy relaxation length is a reciprocal of the scattering degree.

4. The method of claim 1, wherein the obtaining the kinetic energy comprises:
obtaining the kinetic energy of the electron, by integrating an electric force of the electron due to an electric field in the charge trap layer and a rate of a change in the kinetic energy of the electron based on the scattering degree, according to a position of the electron.

5. The method of claim 1, wherein a magnitude of the adjusted electron capturing cross section decreases exponentially according to a magnitude of the kinetic energy of the electron.

6. The method of claim 5, wherein the adjusting the electron capture cross section comprises:
modeling the electron capture cross section using a function having a natural constant as its base and the kinetic energy of the electron as its exponent, to adjust the electron capture cross section.

7. The method of claim 1, wherein the memory device is a charge trap flash (CTF) memory cell.

8. An electronic apparatus comprising:
a processor; and
a memory storing instructions,
wherein, the instructions, when executed by the processor, cause the processor to perform:
determining an injection energy of an electron injected into a memory device, in a simulation;
determining a scattering degree of an electron in a charge trap layer based on the injection energy;
obtaining a kinetic energy of the electron in the charge trap layer based on the scattering degree; and
adjusting an electron capture cross section based on the kinetic energy of the electron.

9. The electronic apparatus of claim 8, wherein the scattering degree increases exponentially according to a magnitude of the injection energy.

10. The electronic apparatus of claim 9, wherein the determining the scattering degree comprises:
modeling an energy relaxation length using a function having a natural constant as its base and the injection energy as its exponent, to determine the scattering degree, and
wherein the energy relaxation length is a reciprocal of the scattering degree.

11. The electronic apparatus of claim 8, wherein the obtaining the kinetic energy comprises:
obtaining the kinetic energy of the electron, by integrating an electric force of the electron due to an electric field in the charge trap layer and a rate of a change in the kinetic energy of the electron based on the scattering degree, according to a position of the electron.

12. The electronic apparatus of claim 8, wherein a magnitude of the adjusted electron capture cross section decreases exponentially according to a magnitude of the kinetic energy of the electron.

13. The electronic apparatus of claim 12, wherein the adjusting the electron capture cross section comprises:
modeling the electron capture cross section using a function having a natural constant as its base and the kinetic energy of the electron as its exponent, to adjust the electron capture cross section.

14. The electronic apparatus of claim 8, wherein the memory device is a charge trap flash (CTF) memory cell.

15. A non-transitory computer-readable medium that stores a computer program, which, when executed by a processor, causes the processor to perform:
determining an injection energy of an electron injected into a memory device, in a simulation;
determining a scattering degree of an electron in a charge trap layer based on the injection energy;
obtaining a kinetic energy of the electron in the charge trap layer based on the scattering degree; and
adjusting an electron capture cross section based on the kinetic energy of the electron.

16. The non-transitory computer-readable medium of claim 15, wherein the scattering degree increases exponentially according to a magnitude of the injection energy.

17. The non-transitory computer-readable medium of claim 16, wherein the determining the scattering degree in the charge trap layer comprises:
modeling an energy relaxation length using a function having a natural constant as its base and the injection energy as its exponent, to determine the scattering degree, and
wherein the energy relaxation length is a reciprocal of the scattering degree.

18. The non-transitory computer-readable medium of claim 15, wherein the obtaining the kinetic energy comprises:
obtaining the kinetic energy of the electron, by integrating an electric force of the electron due to an electric field in the charge trap layer and a rate of a change in the kinetic energy of the electron based on the scattering degree, according to a position of the electron.

19. The non-transitory computer-readable medium of claim 15, wherein a magnitude of the adjusted electron capture cross section decreases exponentially according to a magnitude of the kinetic energy of the electron.

20. The non-transitory computer-readable medium of claim 19, wherein the adjusting of the electron capture cross section comprises:
modeling the electron capture cross section using a function having a natural constant as its base and the kinetic energy of the electron as its exponent, to adjust the electron capture cross section.
